(19) United States
(12) Patent Application Publication
(10) Pub. No.: US 2013/0234135 A1
(43) Pub. Date: Sep. 12, 2013

(54) THIN FILM TRANSISTOR AND METHOD FOR MANUFACTURING SAME

(71) Applicant: FUJIFILM CORPORATION, Tokyo (JP)

(72) Inventors: Fumihiko MOCHIZUKI, Ashigarakami-gun (JP); Masahiro TAKATA, Ashigarakami-gun (JP); Masashi ONO, Ashigarakami-gun (JP); Atsushi TANAKA, Ashigarakami-gun (JP); Masayuki SUZUKI, Ashigarakami-gun (JP)

(73) Assignee: FUJIFILM Corporation, Tokyo (JP)

(21) Appl. No.: 13/871,305

(22) Filed: Apr. 26, 2013

Related U.S. Application Data
(63) Continuation of application No. PCT/JP2011/074289, filed on Oct. 21, 2011.

(30) Foreign Application Priority Data
Oct. 28, 2010 (JP) 2010-242126

(51) Int. Cl. H01L 29/786; H01L 29/66

(52) U.S. Cl. CPC H01L 29/78693; H01L 29/6675
USPC 257/43; 438/151

(57) ABSTRACT

A thin film transistor includes at least a gate electrode, a gate insulating film, an active layer, a source electrode and a drain electrode are provided on a substrate, with the source electrode and the drain electrode being provided on the active layer. The active layer is configured of an amorphous oxide semiconductor. A first amount of moisture present in the gate insulating film is smaller than a second amount of moisture present in the active layer.

### BACKGROUND OF THE INVENTION

The present invention relates to a thin film transistor in which an amorphous oxide semiconductor is used in an active layer and a method of manufacturing the same. Specifically, the present invention relates to a thin film transistor in which a change in TFT characteristics caused by moisture is suppressed and a method of manufacturing the same.

Field effect transistors are used in a unit element of a semiconductor memory integrated circuit, a high-frequency signal amplifying element, a liquid crystal driving element, and the like, and the transistors the thicknesses of which are particularly reduced are used as a thin film transistor (TFT) in a wide range of fields.

As a semiconductor channel layer (active layer) of the field effect transistor, a silicon semiconductor and a compound thereof are often used, and a material, such as single crystal silicon, which operates at low speed is sufficient to be used in a high-frequency amplifying element, an integrated circuit and the like in which a high-speed operation is required. However, amorphous silicon is used for a liquid crystal driving device for display use which requires coping with an increase in area.

In a display field, lightweight and bendable flexible displays have recently been in the spotlight. A resin substrate having a high flexibility is mainly used in such flexible devices. However, since the heat-resistant temperature of the resin substrate is normally 150 to 200° C., and even the heat-resistant temperature of a polyimide-based resin having a high heat resistance is approximately 300° C., these temperatures are lower than that of an inorganic substrate such as a glass substrate.

Since amorphous silicon normally requires a high-temperature heat treatment exceeding 300° C. in a manufacturing process thereof, it is difficult to use amorphous silicon for a supporting substrate such as the flexible substrate in a current display having a low heat resistance.

On the other hand, an In—Ga—Zn—O-based (hereinafter, simply referred to as IGZO) oxide semiconductor which is capable of forming a film at room temperature and capable of exerting performance as a semiconductor even in an amorphous state has been found by Hosono et al. at Tokyo Institute of Technology, and thus is considered promising as a TFT material for a next-generation display (K. Nomura et al, Science, 300 (2003) 1269. and K. Nomura et al, Nature, 432 (2004) 488). An IGZO oxide semiconductor film is in the spotlight because the film can be formed at room temperature and also operates as a TFT, but it is not easy to control, in particular, the stability of the electrical characteristics and to control its characteristics uniformly in a large area.

However, when the IGZO oxide semiconductor is used in an active layer, the active layer has a tendency to fluctuate under the influence of moisture, oxygen or the like, and as a result, a TFT operation may become unstable. For this reason, in TFTs in which the IGZO oxide semiconductor is used in the active layer, various TFTs in which the influence of moisture, oxygen or the like is suppressed are proposed (see, for example, JP 2010-135770 A, JP 2010-186860 A and JP 2008-283046 A).

JP 2010-135770 A discloses that a protective film is provided in order to eliminate the influence of moisture on IGZO from the outside. This means that the electrical characteristics of the IGZO film are influenced by the amount of moisture without being limited to the inside and outside thereof. JP 2010-135770 A discloses a bottom gate type TFT as a device configuration, and discloses that a gate insulating film used in the TFT can be formed of a single layer or a lamination layer of a silicon oxide, a silicon oxynitride, a silicon nitride film, an aluminum oxide, an aluminum nitride, an aluminum oxynitride or a tantalum oxide, and is formed by a sputtering method (see paragraph [0042]).

In addition, JP 2010-135770 A discloses that an insulating film or a gate insulating film is formed of a dense film, and thus moisture or oxygen can be prevented from infiltrating into an oxide semiconductor layer from the substrate side (see paragraph [0043]).

An object of JP 2010-135770 A is to function as a gate insulating film and to prevent moisture/oxygen, Na and the like from being mixed from the outside. However, for example, when SiO₂ is formed as a gate insulating film using a sputtering method, moisture is mixed into SiO₂. JP 2010-135770 A discloses that heat treatment is performed at 200° C. to 600° C., typically 300° C. to 500° C. (see paragraph [0152]). In this temperature, even moisture within SiO₂ can be sufficiently removed. However, in a case of a flexible substrate such a PEN and PES, the substrate cannot endure a thermal process the maximum temperature of which is approximately 200° C. Therefore, it is difficult to eliminate the influence of moisture within SiO₂, and thus it is necessary to reduce the amount of moisture present in the gate insulating film.

In addition, JP 2010-186860 A discloses a field effect transistor in which a protective layer is disposed so as to at least cover a region corresponding to between a source electrode and a drain electrode of an active layer, and a band gap thereof is larger than that of the active layer. JP 2010-186860 A discloses that in the field effect transistor, the influence of moisture or oxygen on the active layer is suppressed and a threshold shift is improved by providing the protective layer and making the band gap of the protective layer larger than that of the active layer.

Further, JP 2008-283046 A discloses an insulated gate transistor in which an active layer is made of an oxide including at least one of In, Ga, and Zn, and in the active layer, desorbed gas observed as water molecules by a thermal desorption spectroscopy is equal to or less than 1.4 pcs/nm³.

JP 2008-283046 A discloses that it is possible to realize an oxide semiconductor thin film having TFT characteristics with a stable threshold voltage and good reproducibility, without showing hysteresis by containing moisture in the active layer, and also discloses that a method of causing moisture to be contained after a film formation includes, for example, annealing in water vapor, implantation of H₂O, or the like.

### SUMMARY OF THE INVENTION

As mentioned above, when the IGZO oxide semiconductor is used in an active layer, the active layer has a tendency to fluctuate under the influence of moisture, oxygen or the like. For example, when the influence of moisture from a gate insulating film or an insulating layer on the active layer is present, there is, naturally, a concern of moisture influencing the electrical characteristics of the active layer formed of an IGZO film, and thus it is necessary to eliminate the influence from the inside of the gate insulating film and the insulating layer contacting the active layer formed of an IGZO film.

However, though JP 2010-135770 A discloses that the insulating film or the gate insulating film is formed of a dense film, and thus moisture or oxygen can be prevented from infiltrating into the oxide semiconductor layer from the substrate side, mixing of impurities such as moisture or oxygen into the oxide semiconductor layer from the insulating film or the gate insulating film is not considered at all.

In addition, though JP 2010-186860 A also discloses that the influence of moisture or oxygen on the active layer is suppressed by making the band gap of the protective layer larger than the active layer, the incorporation of moisture, oxygen or the like into the active layer from the gate insulating film is not considered at all.

Further, in JP 2008-283046 A, though the content of moisture of the oxide semiconductor thin film is defined to equal to or less than 1.4 pcs/nm³ in order to realize TFT characteristics with a stable threshold voltage and good reproducibility, without showing hysteresis, the incorporation of moisture, oxygen or the like into the active layer from the insulating layer is not considered at all.

As stated above, in all of JP 2010-135770 A, JP 2010-186860 A and JP 2008-283046 A, the elimination of the influence of moisture, oxygen or the like from the inside of the gate insulating film and the insulating layer contacting the active layer formed of an IGZO film is not considered at all.

An object of the present invention is to solve problems of the above-mentioned related art, and to provide, particularly, a thin film transistor in which a change in TFT characteristics caused by moisture is suppressed and a method of manufacturing the same.

In order to attain the above-described object, a first aspect of the present invention provides a method of manufacturing a thin film transistor in which at least a gate electrode, a gate insulating film, an active layer, a source electrode, and a drain electrode are provided on a substrate, and the source electrode and the drain electrode are formed on the active layer, comprising the steps of: forming the gate insulating film; and heat-treating the gate insulating film, wherein the active layer is composed of an amorphous oxide semiconductor, and a first amount of moisture present in the gate insulating film is made smaller than a second amount of moisture present in the active layer.

It is preferable to have a step of forming the active layer on the gate insulating film after the step of forming the gate insulating film and the step of heat-treating the gate insulating film.

It is preferable to have a step of forming the active layer on the substrate and a step of forming the source electrode and the drain electrode on the substrate so as to cover a portion of the active layer, before the step of forming the gate insulating film.

It is preferable to have a step of forming the gate electrode on the gate insulating film after the step of forming the gate insulating film and the step of heat-treating the gate insulating film.

Each of the steps is preferably performed at a temperature of equal to or lower than 200° C. The substrate is preferably a flexible substrate.

In the gate insulating film, the amount of moisture released until a temperature reaches 200° C. is preferably equal to or less than 1.53×10²⁰ pcs/cm³.

The amorphous oxide semiconductor contains at least one of In, Ga and Zn, for example.

A second aspect of the present invention provides a thin film transistor in which at least a gate electrode, a gate insulating film, an active layer, a source electrode, and a drain electrode are provided on a substrate, and the source electrode and the drain electrode are formed on the active layer, wherein the active layer is composed of an amorphous oxide semiconductor, and a first amount of moisture present in the gate insulating film is smaller than a second amount of moisture present in the active layer.

The amorphous oxide semiconductor preferably contains at least one of In, Ga and Zn.

The gate insulating film is preferably constituted by any of a single layer of a SiO₂ film, a SiN film, a SiON film, an Al₂O₃ film, a HfO₂ film and a Ga₂O₃ film, or any of a layered product of at least two of a SiO₂ film, a SiN film, a SiON film, an Al₂O₃ film, a HfO₂ film and a Ga₂O₃ film.

The substrate is preferably a flexible substrate.

In the gate insulating film, the amount of moisture released until a temperature reaches 200° C. is preferably equal to or less than 1.53×10²⁰ pcs/cm³.

Preferably, the substrate is formed of a resin film, and a planarization film, or a planarization film and an inorganic protective film are further formed on the resin film.

According to the present invention, it is possible to suppress a change in TFT characteristics caused by moisture in an active layer formed of an amorphous oxide semiconductor, and to thereby improve the stability of the electrical characteristics control of the active layer and the stability of the electrical characteristics of the active layer. For this reason, it is possible to improve the stability of the TFT characteristics control of a thin film transistor, and further to stabilize the TFT characteristics.

### BRIEF DESCRIPTION OF THE DRAWINGS

FIG. 1A is a schematic cross-sectional view illustrating a thin film transistor according to the first embodiment of the present invention, and FIG. 1B is a schematic cross-sectional view illustrating another example of the thin film transistor according to the first embodiment of the present invention.

FIGS. 2A to 2G are schematic cross-sectional views illustrating the method of manufacturing the thin film transistor shown in FIG. 1A in step order.

FIG. 3 is a schematic cross-sectional view illustrating a thin film transistor according to the second embodiment of the present invention.

FIGS. 4A to 4G are schematic cross-sectional views illustrating the method of manufacturing the thin film transistor shown in FIG. 3 in step order.

FIG. 5 is a schematic cross-sectional view illustrating the first sample used in the comprehension of electrical characteristics and the calculation of the amount of H₂O degassing.

FIG. 6 is a graph illustrating a relationship between an annealing temperature and a sheet resistance in the first sample.

FIG. 7 is a graph illustrating a relationship between the surface temperature and the degassing intensity of an IGZO film in the first sample.

FIG. 8 is a graph illustrating a relationship between the surface temperature and the amount of H₂O of the IGZO film in the first sample.

FIG. 9 is a schematic cross-sectional view illustrating the second sample used in the comprehension of electrical characteristics and the calculation of the amount of H₂O degassing.

FIG. 10 is a graph illustrating a relationship between an annealing temperature and a sheet resistance in the second sample, and the relationship between the annealing temperature and the sheet resistance in the first sample.

FIG. 11 is a graph illustrating a relationship between the surface temperature and the degassing intensity of a SiO₂ film in the second sample.

FIG. 12 is a graph illustrating a relationship between the surface temperature and the degassing intensity of the SiO₂ film in the second sample, and a relationship between the surface temperature and the degassing intensity of a SiO₂ film in a sample produced by changing manufacturing conditions of the SiO₂ film of the second sample.

FIG. 13 is a graph illustrating infrared absorption spectrums in the vicinity of peak wavelength of OH radical of the SiO₂ film in the second sample and the SiO₂ film produced by changing the manufacturing conditions in the second sample.

FIG. 14 is a graph illustrating a relationship between an annealing temperature and a sheet resistance in the sample produced by changing the manufacturing conditions of the SiO₂ film of the second sample, and a relationship between the annealing temperature and the sheet resistance in the first sample.

FIG. 15 is a graph illustrating relationships between an annealing temperature and a sheet resistance of a gate insulating film formed of a SiN film and a gate insulating film formed of a Ga₂O₃ film, and a relationship between the annealing temperature and the sheet resistance in the first sample.

FIG. 16 is a graph illustrating the amount of H₂O in various types of films.

FIGS. 17A to 17E are schematic cross-sectional views illustrating the method of manufacturing the transistor of Experimental Examples 2 to 5 in step order.

FIGS. 18A and 18B are schematic cross-sectional views illustrating the method of manufacturing the transistor of Experimental Example 1 in step order.

FIGS. 19A to 19F are graphs illustrating Vg-Ig characteristics of the transistor of Experimental Examples 1 to 6.

### DETAILED DESCRIPTION OF THE INVENTION

Hereinafter, a thin film transistor of the present invention and a method of manufacturing the same will be described in detail on the basis of preferred embodiments shown in the accompanying drawings.

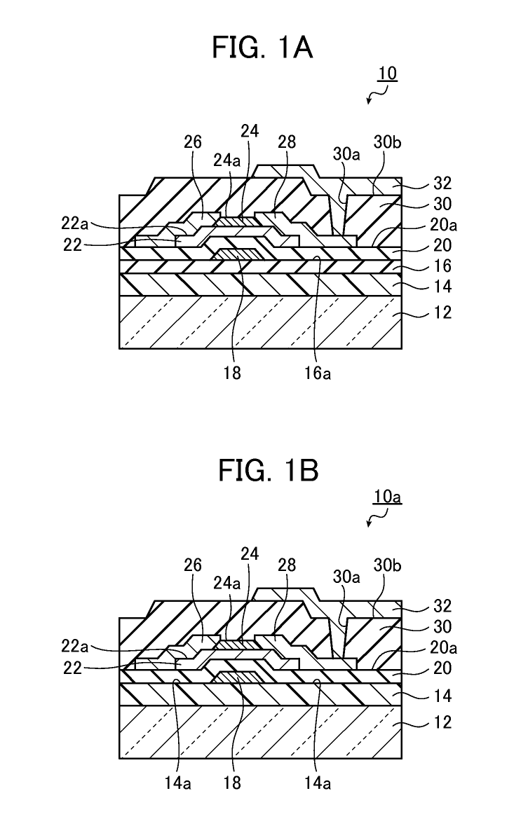

FIG. 1A is a schematic cross-sectional view illustrating a thin film transistor according to the first embodiment of the present invention, and FIG. 1B is a schematic cross-sectional view illustrating another example of the thin film transistor according to the first embodiment of the present invention.

A thin film transistor (hereinafter, simply referred to as a transistor) 10 shown in FIG. 1A is a type of a field effect transistor, and is generally called a bottom gate type transistor.

The transistor 10 shown in FIG. 1A includes a substrate 12, a planarization film 14 provided on the substrate 12, an inorganic surface protective film 16 provided on the planarization film 14, a gate electrode 18, a gate insulating film 20, an active layer 22 functioning as a channel layer, a cap layer 24 functioning as a channel protective layer, a source electrode 26, a drain electrode 28, an insulating film 30, and an electrode 32 connected to the drain electrode 28. The transistor 10 is an active element that has a function of controlling an electric current flowing to a channel region (not shown) of the active layer 22 by applying a voltage to the gate electrode 18 to switch an electric current between the source electrode 26 and the drain electrode 28.

In the transistor 10, the gate electrode 18 is formed on a surface 16a of the inorganic surface protective film 16 provided on the substrate 12, and the gate insulating film 20 is formed on the surface 16a of the inorganic surface protective film 16 so as to cover the gate electrode 18. The active layer 22 is formed on a surface 20a of the gate insulating film 20. The cap layer 24 that covers a channel region of the active layer 22 is provided on a surface 22a of the active layer 22. The source electrode 26 and the drain electrode 28 are formed on the surface 22a of the active layer 22 with the cap layer 24 interposed therebetween.

The source electrode 26 is formed on the surface 20a of the gate insulating film 20 so as to cover a portion of the surface 22a of the active layer 22. In addition, the drain electrode 28 which pairs with the source electrode 26 is formed, opposite to the source electrode 26, on the surface 20a of the gate insulating film 20 so as to cover a portion of the surface 22a of the active layer 22 and a portion of a surface 24a of the cap layer 24. That is, the source electrode 26 and the drain electrode 28 are formed so as to cover a portion of the surface 22a of the active layer 22 and a portion of the surface 24a of the cap layer 24 in a state where the upper side of the surface 24a of the cap layer 24 is opened. The insulating film 30 is formed so as to cover the source electrode 26, the cap layer 24 and the drain electrode 28.

A contact hole 30a reaching the drain electrode 28 is formed in the insulating film 30. The electrode 32 is formed on a surface 30b of the insulating film 30 so as to fill the contact hole 30a.

In the transistor 10, the substrate 12 is not particularly limited, and may be appropriately selected from a Si substrate, a glass substrate, various types of flexible substrate, or the like depending on the intended use.

Since each step of a method of manufacturing the transistor 10 is preferably performed by a low-temperature process of equal to or lower than 200° C., a resin substrate having a low heat resistance can also be suitably used.

As the material of the substrate 12, for example, inorganic materials such as glass and YSZ (yttrium stabilized zirconia) may be used.

In addition, organic materials may also be used as the material of the substrate 12. Examples of the organic material include synthetic resins such as polyester, polystyrene, polycarbonate, polyether sulfone (PES), polyarylate, allyl diglycol carbonate, polyimide (PI), polycycloolefin, norbornene resin, and poly(chlorotrifluoro ethylene); liquid crystal polymers (LCP); or the like.

Here, examples of the above polyester include polyethylene terephthalate (PET), polybutylene terephthalate (PBT), and polyethylene naphthalate (PEN), or the like.

When glass is used in the substrate 12, it is preferable to use alkali-free glass in order to reduce eluted ions from the glass. When soda-lime glass is used in the substrate 12, it is preferable to use one on which barrier coating is performed, for example, with silica.

When an organic material is used in the substrate 12, it is preferable that the organic material is excellent in heat resistance, dimensional stability, solvent resistance, electrical insulation, workability, low air permeability, low hygroscopicity, and the like.

A flexible substrate may also be used for the substrate 12. The thickness of the flexible substrate is preferably set to 50 μm to 500 μm. This is because if the thickness of the flexible substrate is less than 50 μm, it is difficult for the substrate itself to maintain sufficient planarization, and if the thickness of the flexible substrate exceeds 500 μm, the flexibility of the substrate itself becomes poor and thus it is difficult to freely bend the substrate.

Organic-based substrates and metal-based substrates of the following materials and configurations may be used in the substrate 12 as the flexible substrate.

As the flexible substrate, for example, resin substrate and liquid crystal polymer substrate may be used.

The resin substrate is composed of, for example, a polyvinylalcohol-based resin, a polycarbonate derivative (Teijin Ltd.: WRF), a cellulose derivative (cellulose triacetate, cellulose diacetate), a polyolefin-based resin (Nippon Zeon Co., Ltd.: ZEONOR, ZEONEX), a polysulfone-based resin (polyether sulfone, polysulfone), a norbornene-based resin (JSR Co., Ltd.: ARTON), a polyester-based resin (PET, PEN, cross-linked fumaric acid diester), a polyimide-based resin, a polyamide-based resin, a polyamidimide-based resin, a polyarylate-based resin, an acryl-based resin, an epoxy-based resin, an episulfide-based resin, a fluorine-based resin, a silicone-based resin film, a polybenzoazole-based resin, a cyanate-based resin, an aromatic ether-based resin (polyether ketone), a maleimide-olefin-based resin, or the like.

In addition, as the flexible substrate, may be used a composite resin substrate which contains, in the above-mentioned resin substrate, silicon oxide particles, metal nanoparticles, inorganic oxide nanoparticles, inorganic nitride nanoparticles, metal-based/inorganic-based nanofibers, metal-based/inorganic-based microfibers, carbon fibers, carbon nanotubes, glass flakes, glass fibers, glass beads, a clay mineral, or a mica derivative crystal structure.

Further, a substrate configured by a laminated plastic material in which at least one thin glass layer and at least one organic layer composed of the above-mentioned organic material alone are laminated, and a substrate configured by a composite material in which an inorganic layer such as SiO₂, Al₂O₃, and SiOₓN_{y} and an organic layer including the above-mentioned organic material are alternately laminated may be used in the flexible substrate. The composite material mentioned above has an electric barrier performance and a gas barrier performance. Other than the above, a metal substrate such as a stainless steel substrate and an aluminum substrate, and a metal multi-layer substrate in which a stainless steel plate and a different kind of metal plate are laminated may also be used in the flexible substrate, and further, an aluminum substrate with an oxide coating, the surface insulation of which is improved by performing oxidation, for example, anodization on the surface may be used in the flexible substrate.

When a plastic film or the like is used in the substrate 12, an insulating layer is provided thereon if the electrical insulation thereof is insufficient.

The planarization film 14 is used for improving the planarization of the substrate 12. A resin, for example, is used in the formation of the planarization film 14.

The inorganic surface protective film 16 is provided in order to prevent permeation of water vapor and oxygen from the substrate 12, and functions as a moisture permeation prevention layer, that is, a gas barrier layer.

As the material of the inorganic surface protective film 16 which is the moisture permeation prevention layer, that is, the gas barrier layer, inorganic substances such as SiNx, SiO₂, SiON, and Al₂O₃ are suitably used. Further, the moisture permeation prevention layer, that is, the gas barrier layer may have an alternating multilayer structure of the above-mentioned inorganic film and an organic film such as an acryl resin and an epoxy resin. The moisture permeation prevention layer, that is, the gas barrier layer can be formed by, for example, an RF sputtering method or the like.

The gate electrode 18 is formed using, for example, a metal such as Al, Mo, Cr, Ta, Ti, Au or Ag, or an alloy of these metals; an alloy such as Al—Nd or APC; a metal oxide conductive material such as a tin oxide, a zinc oxide, an indium oxide, an indium tin oxide (ITO) or an indium zinc oxide (IZO); an organic conductive compound such as polyaniline, polythiophene or polypyrrole; or a mixture of the above-mentioned materials. As the gate electrode 18, it is preferable to use Mo, a Mo alloy or Cr from the viewpoint of the reliability of TFT characteristics. The thickness of the gate electrode 18 is, for example, 10 nm to 1000 nm. The thickness of the gate electrode 18 is preferably 20 nm to 500 nm, and is more preferably 40 nm to 100 nm.

The method of forming the gate electrode 18 is not particularly limited. The gate electrode 18 is formed using, for example, a wet method such as a printing method and a coating method; a physical method such as a vacuum vapor deposition method, a sputtering method and an ion plating method; a chemical method such as CVD and a plasma CVD method; or the like. An appropriate formation method is selected from among these methods in consideration of fitness for a material constituting the gate electrode 18. When the gate electrode 18 is formed using, for example, Mo or a Mo alloy, a DC sputtering method is used. When an organic conductive compound is used in the gate electrode 18, a wet film forming method is used.

The gate insulating film 20 is formed of, for example, a SiO₂ film, a SiNx film, a SIGN film, an Al₂O₃ film, a HfO₂ film, a Ga₂O₃ film, or the like alone, or a layered product of these films.

The thickness of the gate insulating film 20 is preferably 10 nm to 10 μm. In order to reduce a leakage current and in order to raise voltage resistance, it is necessary to increase the film thickness of the gate insulating film 20 to a certain extent. However, if the thickness of the gate insulating film 20 is increased, a rise in a driving voltage of the transistor 10 is caused. For this reason, the thickness of the gate insulating film 20 is more preferably 50 nm to 1000 nm in case of an inorganic insulator.

If a high dielectric constant insulator such as HfO₂ is used in the gate insulating film 20, the transistor can be driven at a low voltage even in a case where the film thickness thereof is increased, and thus it is particularly preferable to use a high dielectric constant insulator in the gate insulating film 20.

The source electrode 26 and the drain electrode 28 are formed using, for example, a metal such as Al, Mo, Cr, Ta, Ti, Au or Ag, or an alloy of these metals; an alloy such as Al—Nd or APC; or a metal oxide conductive material such as a tin oxide, a zinc oxide, an indium oxide, an indium tin oxide (ITO) or an indium zinc oxide (IZO). The ITO may be an amorphous ITO or a crystallized ITO.

As the source electrode 26 and the drain electrode 28, Mo or a Mo alloy is preferably used from the viewpoint of the reliability of TFT characteristics. The thicknesses of the source electrode 26 and the drain electrode 28 are, for example, 10 nm to 1000 nm.

The source electrode 26 and the drain electrode 28 are formed by, for example, a sputtering method using a metal mask.

The method of forming the source electrode 26 and the drain electrode 28 is not particularly limited. For example, these electrodes are formed using a wet method such as a printing method and a coating method; a physical method such as a photolithographic method, a vacuum vapor deposition method and an ion plating method; a chemical method such as CVD and a plasma CVD method; or the like.

The active layer 22 functions as a channel layer, and is composed of an amorphous oxide semiconductor which is capable of being formed on a plastic film having a low heat resistance. The amorphous oxide semiconductor constituting the active layer 22 contains at least one of In, Ga and Zn.

Examples of the amorphous oxide semiconductor to be used include In₂O₃, ZnO, SnO₂, CdO, an indium zinc oxide (IZO), an indium tin oxide (ITO), a gallium zinc oxide (GZO), an indium gallium oxide (IGO), and an indium gallium zinc oxide (IGZO).

As an example, the amorphous oxide semiconductor constituting the active layer 22 includes homologous compounds expressed by the chemical formula: (In₂₋ₓGaₓ)O₃.(ZnO)ₘ, such as InGaZnO₄ (IGZO) and the like. Here, x is a number satisfying the condition of 0≦x≦2, and m is a natural number.

The thickness of active layer 22 is preferably nm to 100 nm, and is more preferably 2.5 nm to 50 nm.

As described later, the electrical characteristics of the active layer 22 change depending on the amount of moisture contained therein. For this reason, in the transistor 10, the first amount of moisture present in the gate insulating film 20 is smaller than the second amount of moisture present in the active layer 22.

The cap layer 24 covers a channel region of the active layer 22 and protects the channel region. The cap layer 24 is composed of, for example, a SiNx film, a SiO₂ film, or a Ga oxide film. The Ga oxide film is, for example, Ga₂O₃.

The insulating film 30 is formed for the purpose of protecting the cap layer 24, the source electrode 26 and the drain electrode 28 from deterioration due to the atmosphere, and for the purpose of isolating those from an electronic device produced on the transistor.

The insulating film 30 of the present embodiment is formed by, for example, a thermal curing process of a photosensitive acryl resin in a nitrogen atmosphere. As the photosensitive acryl resin, for example, PC405G manufactured by JSR Co., Ltd. is used.

Except for the above-mentioned photosensitive acryl resin, examples of the material capable of being used in the insulating film 30 include a metal oxide such as MgO, SiO, SiO₂, Al₂O₃, GeO, NiO, CaO, BaO, Fe₂O₃, Y₂O₃ or TiO₂, a metal nitride such as SiNx or SiNxOy, a metal fluoride such as MgF₂, LiF, AlF₃ or CaF₂, polyethylene, polypropylene, polymethyl methacrylate, polyimide, polyurea, polytetrafluoroethylene, polychlorotrifluoroethylene, polydichlorodifluoroethylene, a copolymer of chlorotrifluoroethylene and dichlorodifluoroethylene, a copolymer obtained by copolymerizing tetrafluoroethylene and a monomer mixture containing at least one comonomer, a fluorine-containing copolymer having a cyclic structure in a copolymerization main chain, a water absorptive substance having a water absorption ratio of equal to or more than 1%, a moisture-proof substance having a water absorption ratio of equal to or less than 0.1%, or the like.

The method of forming the insulating film 30 is not particularly limited. For example, a vacuum vapor deposition method, a sputtering method, a reactive sputtering method, an MBE (molecular beam epitaxy) method, a cluster ion beam method, an ion plating method, a plasma polymerization method (high-frequency excitation ion plating method), a CVD method, a coating method, a printing method, or a transfer method can be applied to form the insulating film 30.

The electrode 32 is used for taking out an electric current flowing between the source electrode 26 and the drain electrode 28 to the outside. For example, the electrode 32 is configured similarly to the source electrode 26 and the drain electrode 28.

The transistor 10 of the present embodiment is configured to be provided with the inorganic surface protective film 16, but the transistor is not limited thereto. If permeation of moisture, oxygen or the like from the substrate 12 can be prevented only by the planarization film 14 similarly to the inorganic surface protective film 16, the inorganic surface protective film 16 may not be provided as in a transistor 10a shown in FIG. 1B. It is preferable that the inorganic surface protective film 16 is not provided in this way, since the manufacturing steps of the transistor can be simplified.

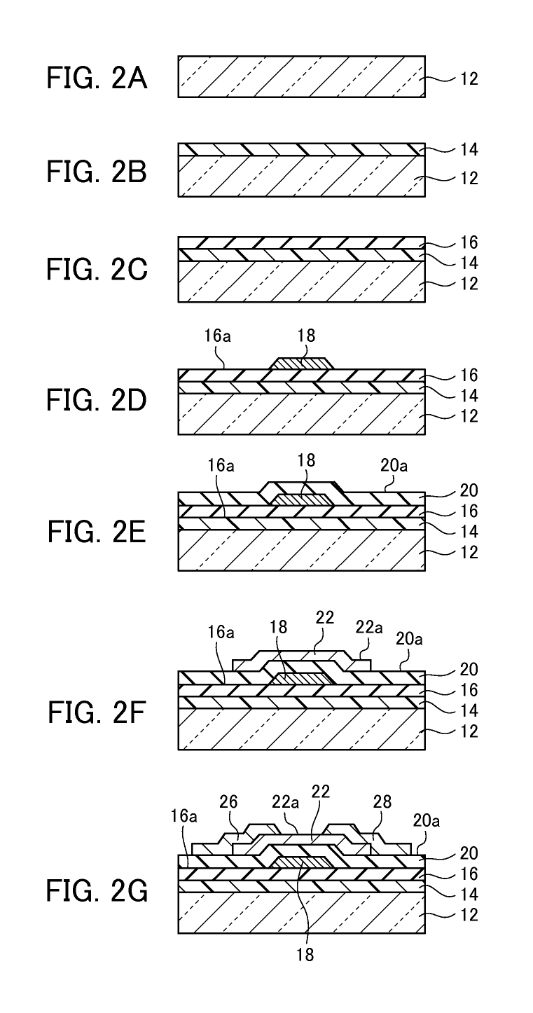

Next, the method of manufacturing the transistor 10 shown in FIG. 1A will be described with reference to FIGS. 2A to 2G.

First, as shown in FIG. 2A, for example, a PEN film is prepared as the substrate 12. Then, ultrasonic cleaning is performed on the substrate 12 using a cleaning agent for substrate, for example, GC6800F (registered trademark) manufactured by BEX Co., Ltd. Thereafter, the substrate is subjected to rinsing and drying, for example, at 150° C. for 30 minutes.

Subsequently, for example, JM531 manufactured by JSR Co., Ltd. is applied onto the surface of the substrate 12 using a spin coater. Thereafter, the coated surface is dried at a temperature of 80° C. for 30 minutes, is further exposed by i-rays (wavelength of 365 nm) having a strength of 140 mJ, and is then baked at a temperature of 200° C. for an hour. Thereby, as shown in FIG. 2B, the planarization film 14 is formed.

Subsequently, a SIGN film having a thickness of 200 nm is formed on the planarization film 14 using, for example, a vacuum vapor deposition method. Thereby, as shown in FIG. 2C, the inorganic surface protective film 16 is formed.

Subsequently, a metal mask (not shown) in which an opening is formed in a pattern shape of the gate electrode 18 is disposed on the surface 16a of the inorganic surface protective film 16. Thereafter, a molybdenum film serving as the gate electrode 18 is formed on the surface 16a of the inorganic surface protective film 16, for example, with a thickness of 50 nm, from the upper side of the metal mask using a DC sputtering method. Thereby, as shown in FIG. 2D, the gate electrode 18 is formed.

Subsequently, a metal mask (not shown) in which an opening is formed in a pattern shape of the gate insulating film 20 is disposed on the surface 16a of the inorganic surface protective film 16 on which the gate electrode 18 is formed. Thereafter, a SiN film serving as the gate insulating film 20 is formed on the surface 16a of the inorganic surface protective film 16, for example, with a thickness of 100 nm so as to cover the gate electrode 18 from the upper side of the metal mask using an RF sputtering method. Thereby, as shown in FIG. 2E, the gate insulating film 20 is formed.

Subsequently, the gate insulating film 20 is subjected to an annealing treatment, for example, at a temperature of equal to or lower than 200° C. Thereby, it is possible to reduce the first amount of moisture present in the gate insulating film 20. In the gate insulating film 20, the amount of moisture released by the time a temperature reaches 200° C. is preferably equal to or less than 1.53×10²⁰ pcs/cm³. In the present invention, the amount of moisture in the gate insulating film 20 can be defined by the amount of moisture released by the time a temperature reaches 200° C. If the first amount of moisture in the gate insulating film 20 is of this extent, it is possible to reduce the influence of the moisture on the active layer 22, and to suppress a change in TFT characteristics.

Subsequently, a metal mask (not shown) in which an opening is formed in a pattern shape of the active layer 22 is disposed on the surface 20a of the gate insulating film 20. Thereafter, an IGZO film (amorphous oxide semiconductor film) serving as the active layer 22 is formed, for example, with a thickness of 50 nm, from the upper side of the metal mask using a DC sputtering method. Thereby, as shown in FIG. 2F, the active layer 22 is formed. The composition of the IGZO film is, for example, InGaZnO₄.

For example, the DC sputtering is performed using a polycrystalline sintered compact having the composition of InGaZnO₄ as a target, and using Ar gas and O₂ gas as a sputtering gas.

Subsequently, a metal mask (not shown) in which an opening is formed in a pattern shape of the source electrode 26 and the drain electrode 28 is disposed on the surface 20a of the gate insulating film 20 on which the active layer 22 is formed. Thereafter, a Mo film serving as the source electrode 26 and the drain electrode 28 is formed on the surface 20a of the gate insulating film 20 in a state where the upper side of the gate electrode 18 is opened, from the upper side of the metal mask using a DC sputtering method. Thereby, as shown in FIG. 2G, the source electrode 26 and the drain electrode 28 are formed.

Subsequently, the cap layer 24 is formed on the surface 22a of the active layer 22 exposed between the source electrode 26 and the drain electrode 28 so as to cover the channel region of the active layer 22. In this case, a Ga oxide film serving as a cap layer 24 is formed, for example, with a thickness of 40 nm by an RF sputtering method using, for example, a metal mask (not shown) in which an opening is formed in a pattern shape of the cap layer 24. Thereby, as shown in FIG. 1A, the cap layer 24 is formed.

The RF sputtering is performed using a gallium oxide (Ga₂O₃) as a target, and using Ar gas and O₂ gas as a sputtering gas.

Subsequently, as a photosensitive acryl resin, for example, PC-405G manufactured by JSR Co., Ltd. is applied with a thickness of 1.5 μm using a spin coater so as to cover the cap layer 24, the source electrode 26 and the drain electrode 28, and then the coated film is subjected to a pre-baking.

A pattern of the acryl resin film is then formed using a photolithographic method. Thereafter, the film is subjected to a post-baking, for example, at a temperature of 180° C. for an hour. Thereby, the insulating film 30 is formed.

In the pattern formation of the acryl resin film, it is preferable to form the contact hole 30a reaching the drain electrode 28 to simplify the manufacturing steps of the transistor.

Subsequently, as a conductive film serving as the electrode 32, for example, a Mo film is formed on the surface 30b of the insulating film 30 so as to fill the contact hole 30a. Thereafter, a pattern of electrode 32 is formed using, for example, a photolithographic method. By the steps mentioned above, the transistor 10 shown in FIG. 1A can be formed.

In the present embodiment, the substrate 12 is not limited to a plastic sheet such as PEN as mentioned above. For example, synthetic silica (Trade Name T-4040) can also be used in the substrate. If the synthetic silica is used in the substrate, the planarization film 14 and the inorganic surface protective film 16 are unnecessary, since the synthetic silica is excellent in planarization and insulation. By using a synthetic silica substrate as the substrate 12 in this manner, it is possible to further simplify the manufacturing steps of the transistor by omitting the planarization film 14 and the inorganic surface protective film 16.

In the present embodiment, the first amount of moisture present in the gate insulating film 20 is made smaller than the second amount of moisture present in the active layer 22, thereby allowing the influence of moisture on the active layer 22 to be reduced, and thus the stability of the electrical characteristics control of the active layer 22 and the stability of the electrical characteristics of the active layer 22 are improved. Therefore, the stability of the TFT characteristics control of the transistor which depends on moisture is particularly improved, and thus the TFT characteristics of the transistor 10 can be stabilized.

Next, the second embodiment of the present invention will be described.

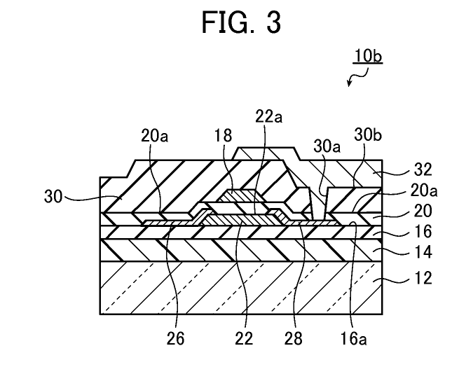

FIG. 3 is a schematic cross-sectional view illustrating a thin film transistor according to the second embodiment of the present invention.

In the present embodiment, the same components as those of the transistor 10 according to the first embodiment shown in FIGS. 1A and 1B are denoted by the same reference symbols, and the detailed description thereof will be omitted.

A transistor 10b of the present embodiment shown in FIG. 3 is generally called a top-gate type. Compared to the transistor 10 shown in FIG. 1A, the transistor 10b has the same configuration as that of the transistor 10 shown in FIG. 1A, except the arrangement position of the gate electrode 18, that the cap layer 24 is not present, that the relationship of the arrangement positions of the active layer 22 with respect to the source electrode 26 and the drain electrode 28 is vertically opposite, and that the active layer 22, the source electrode 26 and the drain electrode 28 are covered by the gate insulating film 20.

In the transistor 10b shown in FIG. 3, the first amount of moisture contained in the gate insulating film 20 and the third amount of moisture contained in the inorganic surface protective film 16 are smaller than the second amount of moisture contained in the active layer 22. Thereby, similarly to the transistor 10 of the first embodiment, the stability of the electrical characteristics control and the stability of the electrical characteristics of the active layer 22 are improved. For this reason, the stability of the TFT characteristics control of the transistor 10b is improved, and further, the TFT characteristics are stabilized.

Next, the method of manufacturing the transistor 10b according to the present embodiment will be described.

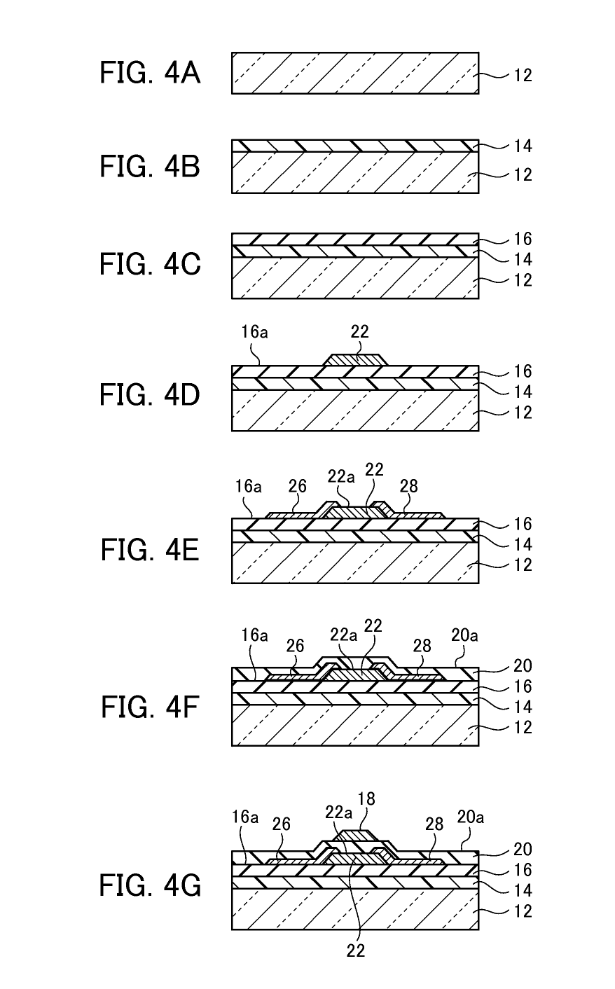

FIGS. 4A to 4F are schematic cross-sectional views illustrating the method of manufacturing the transistor 10b shown in FIG. 3 in step order.

In the present embodiment, the steps of FIGS. 4A to 4C are the same as the above-mentioned steps of FIGS. 2A to 2C according to the first embodiment, and thus the detailed description thereof will be omitted. Accordingly, the step of FIG. 4D and the following steps will be described below.

First, the inorganic surface protective film 16 is subjected to an annealing treatment, for example, at a temperature of equal to or lower than 200° C. Thereby, it is possible to reduce the third amount of moisture present in the inorganic surface protective film 16. In the inorganic surface protective film 16, the amount of moisture released by the time a temperature reaches 200° C. is preferably equal to or less than 1.53×10²⁰ pcs/cm³, similarly to the gate insulating film 20. If the amount is of this extent, it is possible to reduce the influence of moisture on the active layer 22, and to suppress a change in the TFT characteristics.

Subsequently, a metal mask (not shown) in which an opening is formed in a pattern shape of the active layer 22 is disposed on the surface 16a of the inorganic surface protective film 16. Thereafter, an IGZO film serving as the active layer 22 is formed, for example, with a thickness of 50 nm, from the upper side of the metal mask using a DC sputtering method. Thereby, as shown in FIG. 4D, the active layer 22 is formed on the surface 16a of the inorganic surface protective film 16. The composition of the IGZO film is, for example, InGaZnO₄.

Subsequently, a metal mask (not shown) in which an opening is formed in a pattern shape of the source electrode 26 and the drain electrode 28 is disposed on the surface 16a of the inorganic surface protective film 16 on which the active layer 22 is formed. Thereafter, from the upper side of the metal mask using a DC sputtering method, a Mo film serving as the source electrode 26 and the drain electrode 28 is formed with a thickness of 50 nm on the surface 16a of the inorganic surface protective film 16 in a state where the upper side of the active layer 22 is opened. Thereby, as shown in FIG. 4E, the source electrode 26 and the drain electrode 28 are formed.

Subsequently, a metal mask (not shown) in which an opening is formed in a pattern shape of the gate insulating film 20 is disposed on the surface 16a of the inorganic surface protective film 16 on which the active layer 22, the source electrode 26 and the drain electrode 28 are formed. Thereafter, for example, a SiN film serving as the gate insulating film 20 is formed on the surface 16a of the inorganic surface protective film 16, for example, with a thickness of 100 nm so as to cover the active layer 22, the source electrode 26 and the drain electrode 28, from the upper side of the metal mask using an RF sputtering method. Thereby, as shown in FIG. 4F, the gate insulating film 20 is formed.

Subsequently, the gate insulating film 20 is subjected to an annealing treatment, for example, at a temperature of equal to or lower than 200° C. Thereby, it is possible to reduce the first amount of moisture present in the gate insulating film 20, to reduce the influence of moisture on the active layer 22, and to suppress a change in the TFT characteristics.

Subsequently, a metal mask (not shown) in which an opening is formed in a pattern shape of the gate electrode 18 is disposed on the surface 20a of the gate insulating film 20. Thereafter, a molybdenum film serving as the gate electrode 18 is formed on the surface 20a of the gate insulating film 20, for example, with a thickness of 50 nm, from the upper side of the metal mask using a DC sputtering method. Thereby, as shown in FIG. 4G, the gate electrode 18 is formed at the upper side of the active layer 22 and at a position equivalent to the channel region.

Subsequently, as, a photosensitive acryl resin, for example, PC-405G manufactured by JSR Co., Ltd. is applied with a thickness of 1.5 μm using a spin coater so as to cover the gate electrode 18 and gate insulating film 20, and then the coated film is subjected to a pre-baking.

A pattern of the acryl resin film is then formed using a photolithographic method. Thereafter, the film is subjected to a post-baking, for example, at a temperature of 180° C. for an hour. Thereby, the insulating film 30 is formed.

In the pattern formation of the acryl resin film is formed, it is preferable to form the contact hole 30a reaching the drain electrode 28 through the gate insulating film 20 to simplify the manufacturing steps of the transistor.

Subsequently, as a conductive film which becomes the electrode 32, for example, a Mo film is formed on the surface 30b of the insulating film 30 so as to fill the contact hole 30a. Thereafter, a pattern of electrode 32 is formed using, for example, a photolithographic method. By the steps mentioned above, the transistor 10b shown in FIG. 3 can be formed.

The present invention is basically configured as mentioned above. Hereinbefore, the thin film transistor and the method of manufacturing the same according to the present invention have been described in detail. However, the present invention is not limited to the above-mentioned embodiments, and of course, various modifications and changes may be made without departing from the gist of the present invention.

### EXAMPLES

Hereinafter, effects obtained in the present invention by making the first amount of moisture present in the gate insulating film smaller than the second amount of moisture present in the active layer will be described in detail.

First, the electrical characteristics of a single film of an oxide semiconductor layer IGZO were comprehended and the amount of H₂O degassing based on a thermal desorption spectroscopy was calculated.

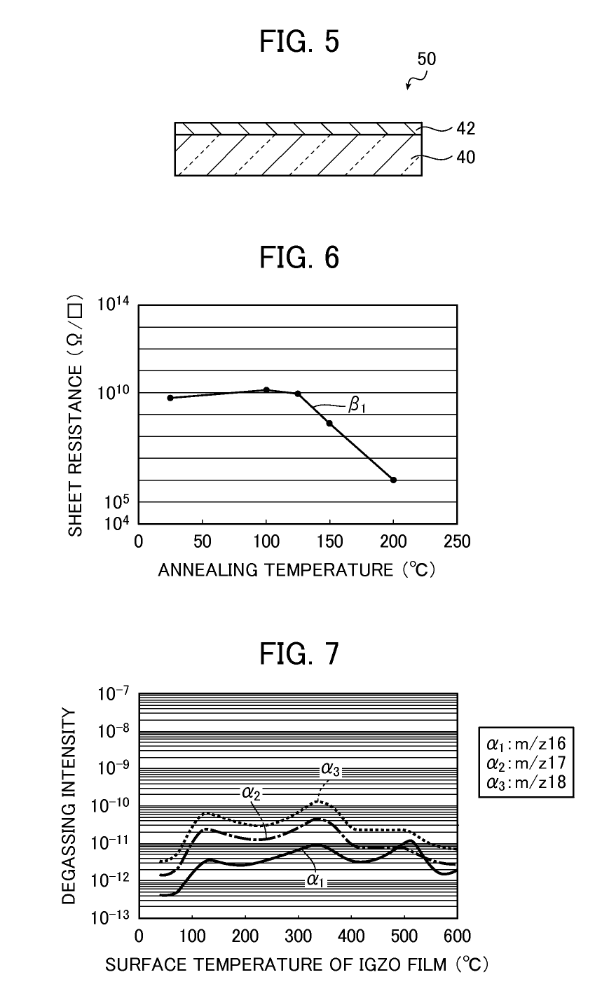

In the comprehension of the electrical characteristics and the calculation of the amount of H₂O degassing, a test substrate 50 in which an IGZO film 42 having a thickness of approximately 50 nm was formed on a film formation substrate 40 which is a synthetic silica substrate was used, as shown in FIG. 5.

As a method of forming the IGZO film 42, a DC sputtering method was used. As sputtering conditions, an ultimate vacuum was set to approximately 3×10⁻⁶ Pa, DC power was set to 50 W, the flow rate of Ar gas was set to 30 SCCM, the flow rate of O₂ gas was set to 0.3 SCCM, a film formation pressure was set to 0.4 Pa, and a film formation time was set to approximately 18 minutes. In addition, the film formation substrate 40 was placed at room temperature (RT) without being heated.

As a target, IGZO (composition of In:Ga:Zn=1:1:1, manufactured by TOSHIMA Manufacturing Co., Ltd.) was used. The composition ratio of the formed IGZO film 42 was In:Ga:Zn=1:0.9:0.7.

After an annealing treatment was performed on the formed IGZO film 42 in a temperature range of RT to 200° C., a sheet resistance (Ω/□) was measured as the electrical characteristics of the IGZO film 42. The sheet resistance was measured using Hiresta MCP-HT450 manufactured by Mitsubishi Chemical Analytech Co., Ltd.

In the annealing treatment, the temperature was maintained on a hot plate for 10 minutes, and then was caused to fall down to room temperature.

The curve β₁ shown in FIG. 6 indicates a relationship between an annealing temperature and a sheet resistance, and indicates a change in the sheet resistance of IGZO characteristics due to annealing. The annealing temperature exceeds 150° C. and then a reduction in resistance progresses. When the IGZO film is formed under the above-mentioned film-forming conditions, and the annealing treatment is performed, the result as shown in FIG. 6 is obtained. The IGZO characteristics shown in FIG. 6 are first defined as electrical characteristics of IGZO alone.

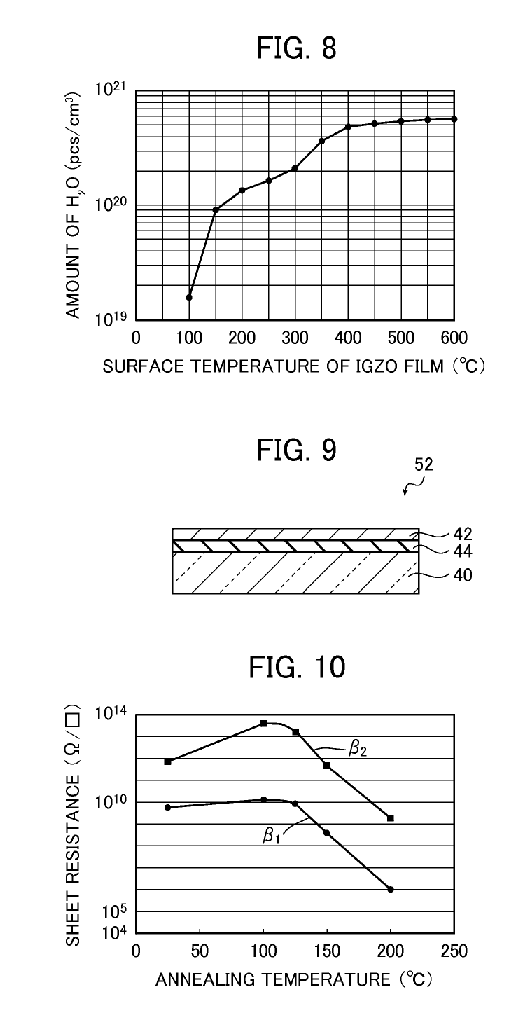

In addition, after the IGZO film 42 was formed on the film formation substrate 40 shown in FIG. 5 under the above-mentioned film-forming conditions, the degassing intensity of H₂O (m/z18) was measured with respect to the IGZO film 42 using thermal desorption spectroscopy (TDS). The result thereof is shown by O₃ of FIG. 7. In addition, FIG. 8 shows the amount of H₂O accumulated.

EMD-WA1000A manufactured by ESCO Ltd. was used in the thermal desorption spectroscopy. In FIG. 7, m/z17 (α₁) and m/z16 (α₂) are fragments from m/z18 (α₃), and indicate that m/z18 is H₂O. Thereby, the amount of H₂O up to 600° C. is approximately 6×10²⁰ pcs/cm³, and the amount thereof from RT (room temperature) to 200° C. is 1.4×10²⁰ pcs/cm³. Accordingly, the amount has a high correlation with the electrical characteristics of the IGZO film. That is, the electrical characteristics of the IGZO film change depending on the amount of H₂O.

Next, with respect to a transistor in which the active layer 22 is an IGZO film and the gate insulating film 20 is located immediately below the active layer 22, such as the bottom gate type transistor 10 shown in FIG. 1A, in order to ascertain the influence of moisture from the gate insulating film, electrical characteristics measurement and degassing analysis were performed using a test substrate 52 having a configuration shown in FIG. 9.

The test substrate 52 shown in FIG. 9 is configured such that a synthetic silica substrate is used as the film formation substrate 40, a SiO₂ film is formed on the film formation substrate 40 as a gate insulating film 44, and the IGZO film 42 is further formed on the gate insulating film 44.

The IGZO film 42 was formed with a thickness of 50 nm under the same film-forming conditions as those of the IGZO film 42 shown in FIG. 5.

As the gate insulating film 44, a SiO₂ film was formed with a thickness of 100 nm using an RF sputtering method.

As film-forming conditions, an ultimate vacuum was set to approximately 5×10⁻⁶ Pa, RF power was set to 200 W, the flow rate of Ar gas was set to 30 SCCM, the flow rate of O₂ gas was set to 0.3 SCCM/1 SCCM, a film formation pressure was set to 0.4 Pa, and a film formation time was set to 60 min. In addition, the film formation substrate was placed at room temperature (RT) without being heated.

SiO₂ having a purity of 5N was used as a target. The SiO₂ film and the IGZO film were transferred in a vacuum state and were continuously formed.

After an annealing treatment was performed on the test substrate 52 shown in FIG. 9, a sheet resistance was measured as electrical characteristics. The result thereof is shown in FIG. 10. The annealing treatment was performed similarly to the above-mentioned test substrate 50 of FIG. 5, and the sheet resistance was measured using the above-mentioned apparatus.

The curve β₂ shown in FIG. 10 indicates a relationship between the annealing temperature and the sheet resistance, and indicates a change in the sheet resistance of IGZO characteristics due to annealing. The curve β₁ of FIG. 6 is shown in FIG. 10 together.

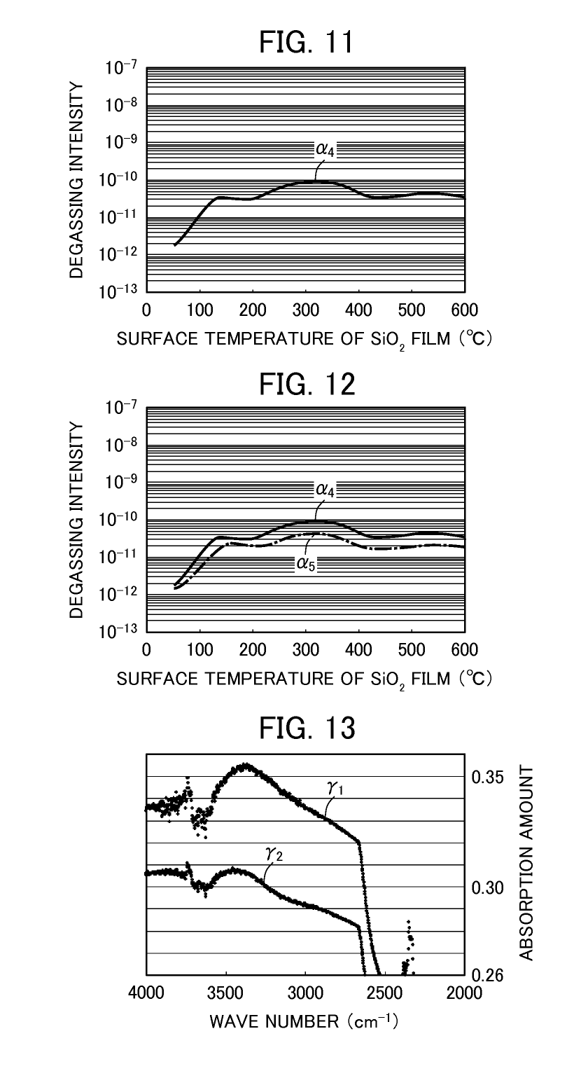

A test substrate (not shown) was prepared by using a synthetic silica substrate as the film formation substrate 40 and forming only a SiO₂ film on the film formation substrate 40, and with respect to the test substrate, the degassing intensity of H₂O (m/z18) was measured using thermal desorption spectroscopy (TDS). The above-mentioned EMD-WA1000A manufactured by ESCO Ltd. was used in the thermal desorption spectroscopy. The result thereof is shown in FIG. 11.

As shown in FIG. 10, the sheet resistance expressed by curve β₂ of the test substrate 52 of FIG. 9 having the SiO₂ film and the IGZO film changes at the high-resistance side than the sheet resistance expressed by curve β₁ of the test substrate 50 of FIG. 5 having only the IGZO film. The IGZO characteristic curve of the curve β₁ and the IGZO characteristic curve of the curve β₂ are similar to each other, but it is understood that a shift occurs at the high-resistance side.

FIG. 11 is data (curve α₄) of H₂O degassing components from the SiO₂ film, and it is well understood that as the temperature is raised, H₂O is released, and the release of H₂O from the SiO₂ film influences the electrical characteristics of the IGZO film.

The total amount of H₂O from the SiO₂ film accumulated until the temperature reached 600° C. calculated by the thermal desorption spectroscopy (TDS) was approximately 3.1×10²¹ pcs/cm³, and the amount of H₂O accumulated until the temperature reached 200° C. was approximately 4×10²⁰ pcs/cm³. The amount of H₂O from the IGZO film shown in FIG. 7 is 1.4×10²⁰ pcs/cm³, and thus the amount of H₂O degassing from the SiO₂ film is obviously larger than the amount of H₂O degassing from the IGZO film, which sufficiently influences the IGZO characteristics. Therefore, it is at least necessary to make the amount of H₂O (amount of degassing) within the SiO₂ film, that is, within the gate insulating film 20 smaller than the amount of H₂O within the IGZO film.

A specific measure to reduce the amount of moisture which is released from the gate insulating film due to heat, time elapsing or operation of the device, that is, a specific measure to reduce the amount of H₂O which is injected into the IGZO film includes a process of forming the IGZO film in a state where moisture is released by previously applying heat up to 200° C. when the gate insulating film 20 (SiO₂ film) is formed, or after the gate insulating film 20 (SiO₂ film) is formed and before the active layer 22 (IGZO film) is formed. In this case, it is preferable that the atmosphere be, for example, a high vacuum of equal to or higher than 1×10⁻⁷ Pa.

As a situation of mixing of H₂O into the SiO₂ film (gate insulating film 20), for example, there are a situation in which H₂O equivalent of the degree of vacuum of a vacuum chamber, in other words, generally a H₂O partial pressure in the vacuum chamber is mixed into the SiO₂ film (gate insulating film 20), and a situation in which a gas released from a chamber wall due to plasma ions or the like is mixed into the SiO₂ film (gate insulating film 20). If a process is terminated in O₂ by forming the SiO₂ film (gate insulating film 20) while raising the flow rate of O₂ gas, the rate of H₂O decreases.

FIG. 12 shows the degassing intensity (α₅ of FIG. 12) of the SiO₂ film formed by a flow of 1 SCCM in FIG. 11, and FIG. 13 shows FT-IR data. In FIG. 13, γ₁ indicates the result in a case where the O₂ gas flow rate is that in the above-mentioned film-forming conditions, and γ₂ indicates the result in a case where the O₂ gas flow rate is 1 SCCM.

As shown in FIG. 12, the amount of H₂O degassing decreases by increasing the O₂ gas flow rate when the SiO₂ film (gate insulating film 20) is formed.

In addition, from FIG. 13, it is understood that OH stretching vibration (3300±300 cm⁻¹) decreases in a case where the O₂ gas flow rate is 1 SCCM. From the result of the TDS shown in FIG. 12, the amount of H₂O until the temperature reaches 600° C. of the SiO₂ film formed under the conditions in which the O₂ gas flow rate is 1 SCCM is approximately 1.4×10²¹ pcs/cm³, and the amount thereof until the temperature reaches 200° C. is approximately 1.99×10²⁰ pcs/cm³, which results in an approximately ½ decrease.

H₂O of the SiO₂ film can be controlled by the O₂ gas flow rate at the time of the film formation, but an increase in the O₂ gas flow rate decreases a film formation rate accordingly. Therefore, it is preferable to release moisture in advance by previously applying heat when the SiO₂ film is formed or after the film is formed (before the IGZO film is formed).

The test substrate 52 shown in FIG. 9 was formed under the above-mentioned film-forming conditions, except that a SiO₂ film was formed on the film formation substrate 40 as the gate insulating film 20 so as to have a thickness of 100 nm, and the O₂ gas flow rate was set to 1 SCCM. After the film formation, an annealing treatment was performed under a vacuum (4×10⁻⁶ Pa), at a temperature of 200° C., for 30 minutes. Thereafter, the film formation substrate 40 and the SiO₂ film were cooled to room temperature, and then the IGZO film was formed with a thickness of 50 nm under the above-mentioned film-forming conditions.

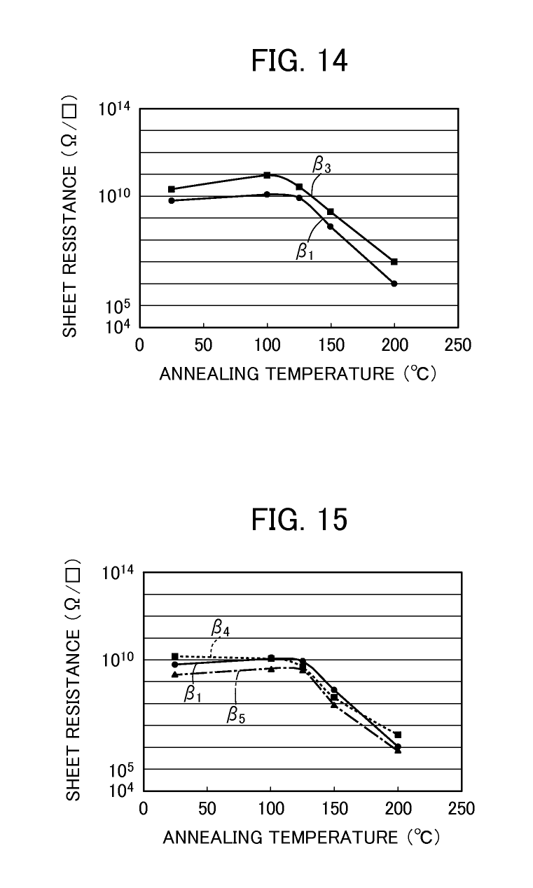

Thereafter, as electrical characteristics, a sheet resistance was measured as mentioned above. The result thereof is shown in FIG. 14. The curve β₃ shown in FIG. 14 indicates a relationship between an annealing temperature and a sheet resistance, and indicates a change in the sheet resistance of the IGZO characteristics due to annealing. The sheet resistance (curve β₁) of the test substrate 50 shown in FIG. 5 is shown in FIG. 14 together.

As shown in FIG. 14, the electrical characteristics when the SiO₂ film is annealed at a temperature of 200° C. are close to the electrical characteristics of the IGZO film. The above electrical characteristics are equivalent to the slightly high-resistance side as a whole, but are closer to the electrical characteristics of the IGZO film when the annealing time is lengthened. In this manner, after a SiO₂ film is formed as the gate insulating film 20, an effect due to the annealing treatment is obtained.

Other than the SiO₂ film, electrical characteristics were comprehended and a degassing analysis was performed with respect to a SiN film and a Ga₂O₃ film which are used as the gate insulating film 20 similarly to the SiO₂ film. Regarding the SiN film and the Ga₂O₃ film, film property thereof was measured by a spectroscopic ellipsometry, conditions setting was performed so that voids became minimum, and film formation thereof was performed under film-forming conditions by which voids become minimum, shown in the following Table 1. The refractive index of the SiN film is 2 in a wavelength of 500 nm, and the refractive index of the Ga₂O₃ film is 1.9 in a wavelength of 500 nm.

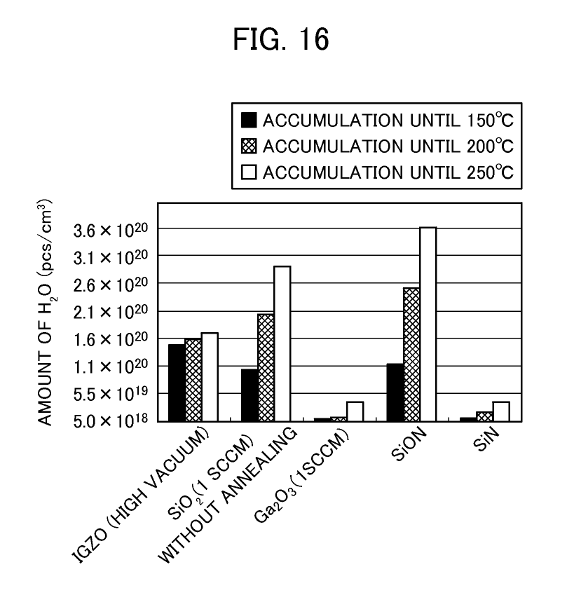

Regarding a test substrate (not shown) having the SiN film and a test substrate (not shown) having the Ga₂O₃ film, as electrical characteristics, sheet resistance was measured as mentioned above. The result thereof is shown in FIG. 15. Further, the amount of H₂O was measured using thermal desorption spectroscopy (TDS). The result thereof is shown in FIG. 16. In FIG. 15, the curve β₄ indicates the result of the test substrate having a SiN film, and the curve β₄ indicates the result of the test substrate having a Ga₂O₃ film. In addition, the sheet resistance (curve β₁) of the test substrate 50 shown in FIG. 5 is shown in FIG. 15 together.

TABLE 1

| | | | Ar | N₂ | O₂ | Film | |
|---|---|---|---|---|---|---|---|
| | | | gas | gas | gas | formation | Back |
| Film | Power | Substrate | flow | flow | flow | pressure | pressure |
| name | (w) | temperature | rate | rate | rate | (Pa) | (Pa) |
| SiN film | 200 | RT | 30 SCCM | 4 SCCM | — | 0.4 | 1.50 × 10⁻⁶ |
| | (RF) | | | | | | |
| Ga₂O₃film | 150 | RT | 30 SCCM | — | 1 SCCM | 0.4 | 4.00 × 10⁻⁶ |
| | (RF) | | | | | | |

As shown in FIG. 15, the characteristics of both the test substrate having a SiN film and the test substrate having a Ga₂O₃ film are generally equivalent to the characteristics of the test substrate 50 shown in FIG. 5.

FIG. 16 shows the amounts of H₂O released from a SiN film and a Ga₂O₃ film, which are calculated by thermal desorption spectroscopy (TDS). FIG. 16 also shows the amounts of H₂O of an active layer (IGZO film), a SiO₂ film in which the O₂ gas flow rate is 1 SCCM and an annealing treatment is not performed, and a SiON film.

As shown in FIG. 16, the SiN film and the Ga₂O₃ film have a smaller amount of H₂O release than that of the SiO₂ film in which an annealing treatment is not performed, and if the amount of H₂O is made smaller, it is possible to reduce an influence on the active layer (IGZO film), and to eliminate the influence as well.

As a gate insulating film, a SiON film can be formed by causing O₂ gas to flow at the time of the formation of the SiN film. Also in the SiON film, if the amount of H₂O is made smaller, it is possible to reduce an influence on the active layer (IGZO film), and to eliminate the influence as well. Similarly, a GaON film can be formed by causing N₂ gas to flow at the time of the formation of the Ga₂O₃ film. Also in the GaON film, if the amount of H₂O is made smaller, it is possible to reduce an influence on the active layer (IGZO film), and to eliminate the influence as well.

As the gate insulating film, the same is true of an Al₂O₃ film and an HfO₂ film. In addition, even when H₂O is present immediately after the formation of the gate insulating film, a releasing treatment (degassing treatment) of moisture may be performed in advance by an annealing treatment.

Regarding performance as the gate insulating film, the field intensities of the SiO₂ film, the SiN film, and the Ga₂O₃ film are 5 MV/cm, and the leakage currents thereof are all in a range of 1×10⁻⁹ to 1×10⁻¹° A/cm², which may be used as the gate insulating film. In a thermal oxide film of SiO₂, the leakage current was 3×10⁻¹⁰ A/cm² in an actual measured value under the same conditions.

### Example 2

Next, as shown in the following Table 2, transistors were produced by changing the types of the gate insulating film, and the TFT characteristics thereof were compared with each other.

In the measurement of the TFT characteristics, semiconductor parameter analyzer 4156C (manufactured by Agilent Technologies Inc.) was used. As the measurement item of the TFT characteristics, Vg-Ig characteristics indicating transistor characteristics were measured.

As the measurement conditions of the transistor characteristics, a drain voltage (Vd) was fixed to 5 V, and a gate voltage (Vg) was changed within a range of −15 V to +15 V, to measure a drain electric current (Id) in each gate voltage (Vg). The sample produced was the bottom gate type TFT (in which the channel length is 180 μm, and the channel width is 1 mm) shown in FIG. 1A.

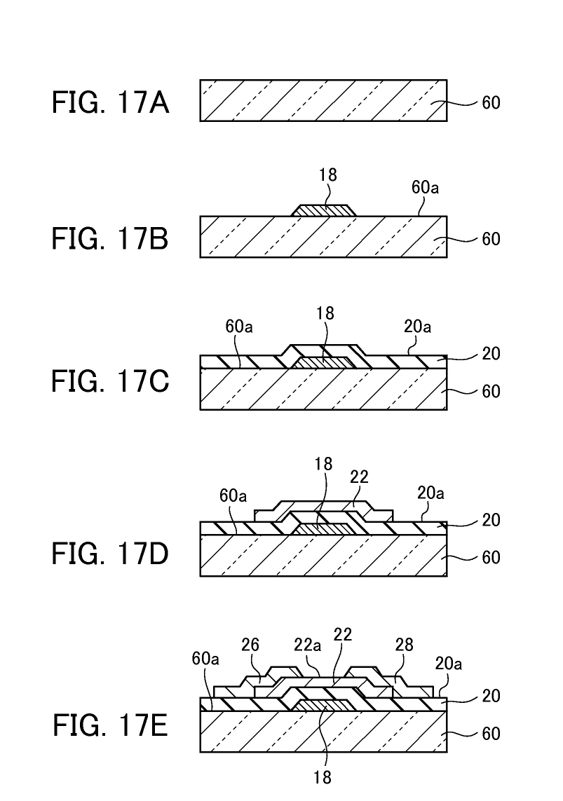

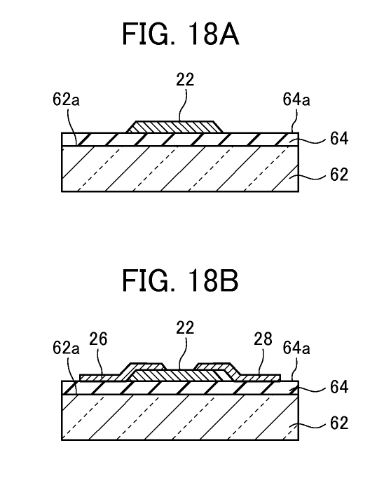

FIGS. 17A to 17E show the method of manufacturing the transistors of Experimental Examples 2 to 5. Further, FIGS. 18A and 18B show the method of manufacturing the transistor of Experimental Example 1.

First of all, as shown in FIG. 17A, a synthetic silica substrate (Trade Name T-4040) is prepared as a substrate 60, alkali ultrasonic cleaning is performed on the substrate, and then pure water rinsing is performed thereon. Thereafter, the substrate is dried at a temperature of 100° C. for 10 minutes.

Subsequently, a metal mask (not shown) in which an opening is formed in a pattern shape of the gate electrode 18 is disposed on the upper side of a surface 60a of the substrate 60. Thereafter, a molybdenum film which becomes the gate electrode 18 is formed on the surface 60a of the substrate 60 with a thickness of 50 nm, from the upper side of the metal mask using a DC sputtering method. Thereby, as shown in FIG. 17B, the gate electrode 18 is formed.

Subsequently, a metal mask (not shown) in which an opening is formed in a pattern shape of the gate insulating film 20 is disposed on the surface 60a of the substrate 60 on which the gate electrode 18 is formed. Thereafter, in accordance with the type of the gate insulating film 20, a SiO₂ film, a SiN film, or a Ga₂O₃ film is formed on the surface 60a of the substrate 60 with a thickness of 100 nm so as to cover the gate electrode 18, from the upper side of the metal mask using an RF sputtering method. Thereby, as shown in FIG. 17C, the gate insulating film 20 is formed.

Regarding the gate insulating film 20, the reactive gases shown in the following Table 2 are appropriately supplied to the gate insulating film 20 depending on the film type.

Subsequently, a metal mask (not shown) in which an opening is formed in a pattern shape of the active layer 22 is disposed on the surface 20a of the gate insulating film 20. Thereafter, an IGZO film (amorphous oxide semiconductor film) serving as the active layer 22 is formed with a thickness of 50 nm from the upper side of the metal mask using a DC sputtering method. Thereby, as shown in FIG. 17D, the active layer 22 is formed.

The DC sputtering is performed, for example, using a polycrystalline sintered compact having the composition of InGaZnO₄ as a target, and using Ar gas and O₂ gas as a sputtering gas.

Subsequently, a metal mask (not shown) in which an opening is formed in a pattern shape of the source electrode 26 and the drain electrode 28 is disposed on the surface 20a of the gate insulating film 20 on which the active layer 22 is formed. Thereafter, a Mo film serving as the source electrode 26 and the drain electrode 28 is formed on the surface 20a of the gate insulating film 20 with a thickness of 50 nm, in a state where the upper side of the gate electrode 18 is opened, from the upper side of the metal mask using a DC sputtering method. Thereby, as shown in FIG. 17E, the source electrode 26 and the drain electrode 28 are formed. Thereafter, an annealing treatment was performed using a hot plate for 10 minutes at a temperature of 200° C. in the atmosphere.

In the present example, since the device operating environment is set to a dry air state, the influence of moisture can be eliminated. For this reason, an insulating film that protects the active layer 22, the source electrode 26 and the drain electrode 28 is not formed. In this manner, device operation ascertainment was performed on the transistor having the configuration shown in FIG. 17E.

In Experimental Example 3, after the gate insulating film was formed, an annealing treatment was performed using a hot plate for 10 minutes at a temperature of 200° C. in the atmosphere.

When a P-type silicon substrate is used in a substrate 62, the substrate 62 is thermally oxidized, and as shown in FIG. 18A, a SiO₂ film (thermal oxide film) is formed on a surface 62a of the substrate 62 as a gate insulating film 64.

A metal mask (not shown) in which an opening is formed in a pattern shape of the active layer 22 is disposed the upper side of a surface 64a of the gate insulating film 64. Thereafter, as mentioned above, an IGZO film serving as the active layer 22 is formed with a thickness of 50 nm from the upper side of the metal mask using a DC sputtering method. Thereby, as shown in FIG. 18A, the active layer 22 is formed.

Subsequently, a metal mask (not shown) in which an opening is formed in a pattern shape of the source electrode 26 and the drain electrode 28 is disposed on the surface 64a of the gate insulating film 64 on which the active layer 22 is formed. Thereafter, a Mo film serving as the source electrode 26 and the drain electrode 28 is formed on the surface 64a of the gate insulating film 64 with a thickness of 50 nm, in a state where the upper side of the gate electrode 18 is opened, from the upper side of the metal mask using a DC sputtering method. Thereby, as shown in FIG. 18B, the source electrode 26 and the drain electrode 28 are formed. Thereafter, an annealing treatment was performed using a hot plate for 10 minutes at a temperature of 200° C. in the atmosphere.

Also in Experimental Example 1, since the device operating environment is set to a dry air state, an insulating film that protects the active layer 22, the source electrode 26 and the drain electrode 28 are not formed. In this manner, device operation ascertainment was performed on the transistor having the configuration shown in FIG. 18B. Meanwhile, in Example 1, the P-type silicon substrate (substrate 62) shown in FIG. 18B serves as a gate electrode.

Experimental Example 6 is a transistor produced by the steps shown in FIGS. 2A to 2G using a PEN film in the substrate 12, using JM531 manufactured by JSR Co., Ltd. in the planarization film 14, and using SiON in the inorganic surface protective film 16. Also in Experimental Example 6, since the device operating environment is set to a dry air state, an insulating film that protects the active layer 22, the source electrode 26 and the drain electrode 28 are not formed. In this manner, device operation ascertainment was performed on the transistor having the configuration shown in FIG. 2G.

TABLE 2

| | | | Reactive | | |
|---|---|---|---|---|---|
| | Type of | | Gas at the | | |
| | gate | | time of | | |
| | insulating | Sub- | film | Annealing | Annealing |
| | film | strate | formation | temperature | timing |
| Experimental | SiO₂ | Si—P | Thermal | 200° C. | After |
| Example 1 | (thermal | type | oxidation | | device |
| | oxidation) | | | | formation |
| Experimental | SiO₂ | Silica | O₂ gas: | 200° C. | After |
| Example 2 | | | 1 SCCM | | device |
| | | | | | formation |
| Experimental | SiO₂ | Silica | O₂ gas: | 200° C. | After |
| Example 3 | | | 1 SCCM | | SiO₂ film |
| | | | | | formation + |
| | | | | | after |
| | | | | | device |
| | | | | | formation |
| Experimental | SiN | Silica | N₂ gas: | 200° C. | After |
| Example 4 | | | 4 SCCM | | device |
| | | | | | formation |
| Experimental | Ga₂O₃ | Silica | O₂ gas: | 200° C. | After |
| Example 5 | | | 1 SCCM | | device |
| | | | | | formation |
| Experimental | SiN | PEN | N₂ gas: | 200° C. | After |
| Example 6 | | | 4 SCCM | | device |
| | | | | | formation |

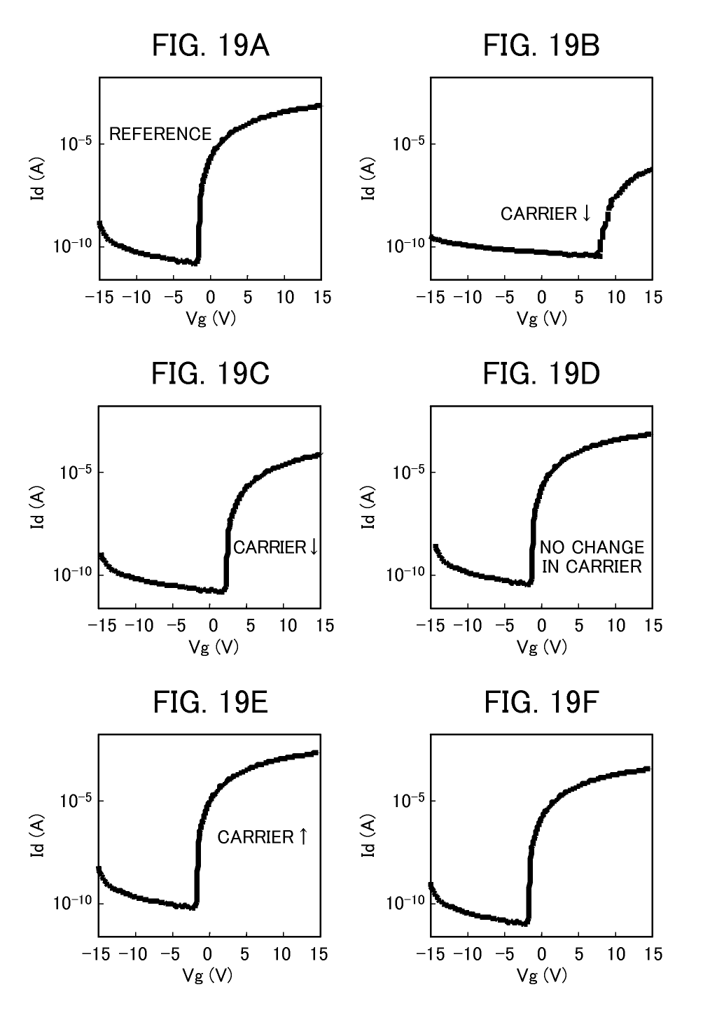

FIGS. 19A to 19F are graphs illustrating the results of Experimental Examples 1 to 6, respectively. Experimental Example 1 (configuration of FIG. 18B) shown in FIG. 19A serves as a reference.

In Experimental Example 2 shown in FIG. 19B, a shift to the +(positive) side due to a decrease in the number of carriers is observed compared to Experimental Example 1 (reference). It is considered that this is because moisture within the gate insulating film is shifted to (influences on) the IGZO film side (active layer side) by annealing in Experimental Example 2.

In Experimental Example 3 shown in FIG. 19C, though a slight shift to the +(positive) side due to a decrease in the number of carriers is observed compared to Experimental Example 1 (reference), the shift is in an allowable range. It is considered that this is because the first amount of moisture of the gate insulating film is smaller than the second amount of moisture of the active layer, since in Experimental Example 3, an annealing treatment is performed after the formation of the gate insulating film and before the formation of the active layer.

In Experimental Example 4 shown in FIG. 19D, a change in the number of carriers is not observed, and thus Experimental Example 4 is substantially the same as Experimental Example 1 (reference). In Experimental Example 5 shown in FIG. 19E, though a slight shift to the − (negative) side due to an increase in the number of carriers is observed compared to Experimental Example 1 (reference), the shift is in an allowable range.

In Experimental Example 6 shown in FIG. 19F, though a slight shift to the − (negative) side is observed compared to Experimental Example 1 (reference), the shift is an allowable range.

In Experimental Examples 4 to 6, the gate insulating film is a SiN film or a Ga₂O₃ film. As described above, Experimental Examples 4 to 6 are in an allowable range, and it is considered that this is because in the SiN film and the Ga₂O₃ film, the amount of moisture is smaller than the second amount of moisture of the active layer, as shown in FIG. 16.

What is claimed is:

1. A method of manufacturing a thin film transistor in which at least a gate electrode, a gate insulating film, an active layer, a source electrode, and a drain electrode are provided on a substrate, and the source electrode and the drain electrode are formed on the active layer, comprising the steps of:
forming the gate insulating film; and
heat-treating the gate insulating film,
wherein the active layer is composed of an amorphous oxide semiconductor, and
a first amount of moisture present in the gate insulating film is made smaller than a second amount of moisture present in the active layer.

2. The method of manufacturing a thin film transistor according to claim 1, having a step of forming the active layer on the gate insulating film after the step of forming the gate insulating film and the step of heat-treating the gate insulating film.

3. The method of manufacturing a thin film transistor according to claim 1, having a step of forming the active layer on the substrate and a step of forming the source electrode and the drain electrode on the substrate so as to cover a portion of the active layer, before the step of forming the gate insulating film.

4. The method of manufacturing a thin film transistor according to claim 3, having a step of forming the gate electrode on the gate insulating film after the step of forming the gate insulating film and the step of heat-treating the gate insulating film.

5. The method of manufacturing a thin film transistor according to claim 1, wherein each of the steps is performed at a temperature of equal to or lower than 200° C.

6. The method of manufacturing a thin film transistor according to claim 1, wherein the substrate is a flexible substrate.

7. The method of manufacturing a thin film transistor according to claim 1, wherein in the gate insulating film, the amount of moisture released until a temperature reaches 200° C. is equal to or less than 1.53×10²⁰ pcs/cm³.

8. The method of manufacturing a thin film transistor according to claim 1, wherein the amorphous oxide semiconductor contains at least one of In, Ga and Zn.

9. A thin film transistor in which at least a gate electrode, a gate insulating film, an active layer, a source electrode, and a drain electrode are provided on a substrate, and the source electrode and the drain electrode are formed on the active layer,
wherein the active layer is composed of an amorphous oxide semiconductor, and
a first amount of moisture present in the gate insulating film is smaller than a second amount of moisture present in the active layer.

10. The thin film transistor according to claim 9, wherein the amorphous oxide semiconductor contains at least one of In, Ga and Zn.

11. The thin film transistor according to claim 9, wherein the gate insulating film is constituted by any of a single layer of a SiO₂ film, a SiN film, a SiON film, an Al₂O₃ film, a HfO₂ film and a Ga₂O₃ film, or any of a layered product of at least two of a SiO₂ film, a SiN film, a SiON film, an Al₂O₃ film, a HfO₂ film and a Ga₂O₃ film.

12. The thin film transistor according to claim 9, wherein the substrate is a flexible substrate.

13. The thin film transistor according to claim 9, wherein in the gate insulating film, the amount of moisture released until a temperature reaches 200° C. is equal to or less than 1.53×10²⁰ pcs/cm³.

14. The thin film transistor according to claim 9, wherein the substrate is formed of a resin film, and a planarization film, or a planarization film and an inorganic protective film are further formed on the resin film.
